(19) United States
(12) Patent Application Publication
(10) Pub. No.: US 2018/0277362 A1
(43) Pub. Date: Sep. 27, 2018

(54) Method of Surface Localized Pore Sealing of Porous Dielectric Material

(71) Applicants: Lam Research Corporation, Fremont, CA (US); Korea Advanced Institute of Science and Technology, Daejeon (KR)

(72) Inventors: Byung Jin Cho, Daejeon (KR); Sung Gap Im, Daejeon (KR); Seong Jun Yoon, Daejeon (KR); Kwanyong Pak, Daejeon (KR); Hyungsuk Alexander Yoon, San Jose, CA (US)

(21) Appl. No.: 15/923,918

(22) Filed: Mar. 16, 2018

(30) Foreign Application Priority Data
Mar. 22, 2017 (KR) 10-2017-0036080

(51) Int. Cl. H01L 21/02; H01L 21/768; H01L 23/532; H01L 23/522; B05D 1/00; B05D 3/02

(52) U.S. Cl. CPC H01L 21/02277; H01L 21/02118; H01L 21/02203; H01L 21/7682; H01L 2221/1047; H01L 23/5226; B05D 1/60; B05D 3/0254; H01L 23/5329

(57) ABSTRACT

Provided are a method of locally sealing only pores present in a surface part of a porous dielectric material by forming a polymer thin film through an initiated chemical vapor deposition (iCVD) method using an initiator, and a method of minimizing an increase in a dielectric constant induced therefrom.

### CLAIM OF PRIORITY

This application claims priority from Korean Application No. 2017-0036080, filed on Mar. 22, 2017, and entitled “Method of Surface Localized Pore Sealing of Porous Dielectric Material,” which is herein incorporated by reference.

### TECHNICAL FIELD

The following disclosure relates to a method of sealing pores present in a surface of a porous ultralow-k dielectric material by forming a polymer thin film via an initiated chemical vapor deposition (iCVD) method and a method of minimizing an increase in a dielectric constant induced therefrom.

### BACKGROUND

As a minimum feature size of semiconductor devices is decreased, a distance between interconnects should also be decreased. Therefore a capacitance between metal lines necessarily increases as the interconnect width decreases. An increase in line-to-line capacitance leads to an increase in RC-delay, cross-talk noise, and power dissipation, which cause severe problems in modern integrated circuit (IC) chips. Therefore, to reduce the line-to-line capacitance, semiconductor industries have introduced low dielectric constant (k) dielectric materials. The most popular method to lower k of dielectric materials is to insert pores in the dielectric materials because the air or vacuum has the lowest k value in the nature, which is theoretically 1. Therefore, the effective k values of the porous dielectric materials could be much lower than dense dielectric materials where the k value of the state-of-the-art porous low-k dielectric material is as low as 2.4. However, the introduction of the pores in the dielectric material makes it difficult to be implemented in IC fabrication processes due to several reasons. For example, the presence of the pores reduces the mechanical/chemical strength of the dielectric materials by increasing a discontinuity of dielectric molecules, which makes it extremely vulnerable to process-related damages during the fabrication processes. In addition, since the pores in the dielectric materials are mutually interconnected, harmful species generated during the fabrication processes, such as plasma, chemicals, moisture, or even metal particles, is able to easily penetrate into the bulk dielectric through the interconnected pores. Consequently, the original properties of low-k dielectric materials, such as low-k characteristic and insulation performance, may be easily degraded.

It has been considered that the problems could be solved by sealing the surface pores of the porous low-k dielectric materials.

For example, it has been studied that densifying the surface of the porous low-k dielectric materials by plasmas to seal outer surfaces of the porous materials. However, it inevitably causes severe plasma damage to the porous dielectric materials and consequently the k value of the dielectric materials increases severely. Further, if the porosity increases to reduce the k value of the dielectric materials, the damage to the porous dielectric materials becomes much more severe and degrades the unique properties of the porous low-k dielectric materials.

As another method, it has been intensively studied to form a dense thin layer by depositing an additional film on the surface of the porous low-k dielectric materials. However, there is a problem in that as the porosity of the dielectric materials increases, the penetration depth of the pore sealant also increases. Furthermore, depending on deposition methods, it may be difficult to deposit a conformal layer at extremely narrow trench/vias required in the modern back-end of line (BEOL) fabrication.

Likewise, the conventional pore sealing methods have their own disadvantages in being utilized in modern fabrication processes, such as a severe loss of the original low-k characteristic, compatibility with current BEOL processes, capability of mass production, etc., and consequently, none of them has been adopted to industries so far.

Therefore, it is essential to provide a novel method of sealing the porous surfaces of dielectric materials, which is able to maintain the original low-k nature as many as possible while sealing the porous surface hermetically.

### SUMMARY

As a result of a number of studies to solve the above problems, the present invention provides a new sealing technique capable of substantially maintaining physical properties of a porous dielectric material before sealing as they are by minimizing a change rate of a dielectric constant while sealing pores of a surface of the porous dielectric material. In addition, the present invention provides a porous composite dielectric material in which a change rate of a dielectric constant is minimized while sealing open pores of the surface by the above sealing technique.

An embodiment of the present invention is directed to providing a novel surface sealing method in which a polymer thin film is formed on a surface of a porous dielectric material by an initiated chemical vapor deposition (iCVD) method using a polymerizable monomer and an initiator, thereby locally closing only pores of the surface of the dielectric material to minimize a decrease in internal porosity.

More specifically, in forming the polymer thin film that seals the open pores of the surface of the porous dielectric material, the present invention is to provide a method of forming a polymer thin film only in a surface part by adsorbing monomers to pores mutually interconnected in the porous dielectric material, thereby forming a dielectric material that appears to be temporarily dense, and by reacting only the monomers that are exposed to the surface part of the material, using the initiator. Here, the method includes locally removing unreacted monomers, the initiator, and oligomers formed by polymerization of some monomers which are trapped in the pores interconnected in the material after the polymer thin film is formed on the surface. An embodiment of the present invention is directed to providing a method of preparing a novel porous composite dielectric material that seals only pores present in a surface part of the porous dielectric material and simultaneously minimizes an increase in dielectric constant after sealing by locally removing remaining internal compounds inevitably formed during formation of the polymer thin film.

In addition, the present invention aims to locally seal the pores of the surface of the porous dielectric material or to reduce only porosity, thereby minimizing a reduction in total porosity of the porous composite dielectric material simultaneously while reducing open porosity to maintain original properties of the dielectric material or to minimize a change in the original properties.

In order to achieve the above-described objects, the present invention relates to a method of minimizing a change rate of a dielectric constant by repeating a step of forming a polymer thin film by an initiated chemical vapor deposition (iCVD) method and a heat treatment step when sealing open pores of a surface of a porous material, for example, a porous dielectric material constituting a semiconductor device, and a porous composite dielectric material in which pores of the surface are sealed with the polymer thin film while the change rate of the dielectric constant is minimized by the above method.

Specifically, the present invention relates to a novel method of sealing the open pores present in the surface of a low-k porous dielectric material having k defined as 2.4 to 3.6 or a ultra low-k porous dielectric material having k defined as less than 2.4, wherein in sealing the open pores of the surface through the initiated chemical vapor deposition (iCVD) process using an initiator, process conditions such as a substrate temperature, pressure, etc., are controlled so that monomers to be vaporized and injected are smoothly adsorbed to the surface of the dielectric material and internal pores, and unreacted materials trapped in pores mutually interconnected in the porous dielectric material are smoothly removed by performing the heat treatment by specific means, etc., and thus, the change rate of the dielectric constant may be minimized.

In one general aspect, a porous composite dielectric material includes: a porous dielectric material, and a polymer thin film formed on one surface or both surfaces of the porous dielectric material, wherein pores of a surface part of the porous dielectric material are sealed by the polymer thin film, and a change rate of a dielectric constant k satisfies Equation 1 below:

0≤[(k₂−k₁)/k₁]×100≤15 [Equation 1]

In Equation 1 above, k₁ is a dielectric constant of the porous dielectric material and k₂ is a dielectric constant of the porous composite dielectric material.

In another general aspect, a method of preparing a porous composite dielectric material includes: a) placing a porous dielectric material on a substrate of an initiated chemical vapor deposition (iCVD) chamber; b) injecting a vaporized monomer or a vaporized monomer and a vaporized initiator into the chamber, and maintaining the chamber for a predetermined period of time, thereby adsorbing the monomer to a surface and internal pores of the porous dielectric material; c) forming a polymer thin film by applying heat while injecting the vaporized monomer and the vaporized initiator into the chamber, to thereby induce a chain polymerization reaction so that the monomers in a surface part of the porous dielectric material are polymerized; d) performing a heat treatment on the porous composite dielectric material having the polymer thin film formed thereon at a temperature of the substrate when the polymer thin film is formed or higher to 400° C. or lower; and e) repeating at least two cycles, wherein one cycle includes steps b), c), and d) that are sequentially performed.

### BRIEF DESCRIPTION OF THE DRAWINGS

FIG. 1 shows a reaction mechanism of a step of forming a polymer thin film and a heat treatment step.

FIG. 2 shows a reaction mechanism in which a step of forming a polymer thin film and a heat treatment step are repeated.

FIGS. 3A-3E show graphs for a change in dielectric constant according to cycle repetition of Example 1.

FIGS. 4A-4E show graphs for a change in refractive index according to the cycle repetition of Example 1.

FIGS. 5A-5C is a scanning transmission electron microscopy image according to Example 1.

### DETAILED DESCRIPTION OF EMBODIMENTS

Hereinafter, the present invention is described in detail through specific exemplary embodiments or examples including the accompanying drawings. Meanwhile, the following exemplary embodiments and examples are provided as a reference for explaining the present invention in detail, and therefore, the present invention is not limited thereto, but may be implemented in various ways.

Unless defined otherwise, all technical and scientific terms used herein have the same meanings generally understood by those skilled in the art to which the present invention pertains. Terms used in the specification of the present invention are to effectively describe specific exemplary embodiments, but are not intended to limit the present invention.

It is intended that singular forms used in the appended specification and claims include plural forms unless otherwise indicated in the context.

Hereinafter, ‘porosity’ in the present invention includes all porosities present in a porous dielectric material, that is, both open porosity and closed porosity, and the porosity is not described separately since it is measured by conventional methods. The ‘open porosity’ refers to a porosity at which pores accessible by external materials, such as gases, chemical species, etc., occupy since the pores are interconnected and connected to the outside. The ‘closed porosity’ refers to completely trapped pores that are not accessible from the outside.

A ‘polymer thin film’ in the present invention is basically a thin film formed by being deposited near a surface of the porous dielectric material, and may be formed in the inside of open pores near the surface of the porous dielectric material, or in a continuous film form on top of the surface of the porous dielectric material, or these two forms may coexist.

The ‘porous dielectric material’ in the present invention includes a low-k porous dielectric material with k defined as 2.4 to 3.6 and a ultra low-k porous dielectric material with k defined as less than 2.4. In addition, the porous dielectric material is not limited as long as it is a general material applied to a semiconductor device.

A ‘temperature’ in the heat treatment in the present invention refers to a temperature in a chamber and a temperature directly or indirectly applied to a substrate.

A ‘surface part’ in the present invention includes a surface of the porous dielectric material, open pores formed on the surface, and a portion of the pores leading to the inside from the open pores.

An initiated chemical vapor deposition (iCVD) process using an initiator is a process of forming a polymer thin film on the surface of the porous dielectric material through a vapor polymerization reaction in which a polymer polymerization reaction and a film formation process are simultaneously performed by vaporizing monomers and the initiator. That is, the iCVD process is a process in which the vaporized monomers are polymerized on the surface of the porous dielectric material inside an iCVD chamber to form the polymer thin film, wherein the polymer polymerization reaction and thin film deposition are simultaneously performed in one process.

When the initiator and the monomer are simply mixed, the polymerization reaction does not occur. However, when the initiator is decomposed by a high-temperature filament located in a gas phase reactor to generate radicals, the monomer is activated and a chain polymerization reaction is performed.

The present inventors found that when various kinds of polymer thin films were formed by the iCVD process, the open pores could be reduced while maintaining the porous form inside the porous dielectric material as it is. In addition, the present inventors found that when temperature and pressure in a reactor chamber are controlled at the time of injecting the monomer and the initiator, the monomer could be well filled in the open pores of the surface of the porous dielectric material.

A process of forming a thin film on the surface of the porous dielectric material to seal the pores by the iCVD process of the present invention is as follows. When the vaporized monomer is supplied or the vaporized monomer and initiator are simultaneously supplied to an inner part of the iCVD chamber, it is preferred that a vapor pressure of the monomer is selected to be lower than that of the initiator, and thus, only the majority of the monomer is adsorbed to the porous dielectric material so that adsorption of the initiator is minimized to a negligible extent. Further, since a vapor pressure inside the pores is generally lower than that on a flat surface with respect to the same gas molecules, gas molecule adsorption inside the pores much more easily occurs as compared to the flat surface. Thus, the monomers injected into the iCVD chamber are adsorbed and filled from the open pores of the porous dielectric material. Here, by controlling the pressure in the chamber and the temperature of the porous dielectric material, the monomers may be locally filled only in a part of the open pores of the porous dielectric material or the monomers may be adsorbed up to the surface of the porous dielectric material. When the adsorption of the monomers reaches an equilibrium state after an appropriate time, a temperature of a heating filament in the iCVD vacuum chamber is increased. Here, the heating filament is heated to a temperature at which the monomers are not damaged while simultaneously decomposing and radicalizing the initiator. When radicals begin to be generated, polymerization starts from the monomers filled in the open pores near the surface of the porous dielectric material or from the monomers adsorbed on the surface because the radicals are able to reach only the surface of the porous dielectric material due to the property of the polymer dielectric material in which the open pores are filled with the monomers.

When the thin film is formed in the vicinity of the surface of the porous dielectric material, unreacted monomers, the initiator, and oligomers formed by polymerization of some monomers, etc., are trapped and remain inside the porous dielectric material.

Since the trapped species are thermally very unstable, the open pores of the surface significantly degrade thermal stability of a sealed porous composite dielectric material. In addition, the porosity of the porous composite dielectric material is reduced due to the presence of the trapped materials, which causes a problem in that an effective dielectric constant (k_{eff}) is increased. Accordingly, it is necessary to remove or immobilize various trapped compounds as described in the present invention, thereby suppressing deterioration of process stability due to reaction, leakage or deterioration thereof during post-processes.

The present invention is characterized in that the open pores of the porous dielectric material are filled with the monomers before forming the polymer thin film, thereby having the same effect as a dielectric material which is temporarily dense, and after the polymer thin film is formed, a heat treatment process is added as a method of removing the trapped materials inside the porous dielectric material. A temperature condition at the time of the heat treatment process is not limited. However, a temperature of the heat treatment process is higher than a substrate temperature of the chamber at the time of forming the polymer thin film in the step of forming the polymer thin film and is 400° C. or less, thereby smoothly removing or inactivating the trapped materials.

In addition, an atmosphere in the heat treatment process may be maintained in a vacuum state, thereby effectively removing the trapped compounds. Otherwise, the atmosphere in the heat treatment process may be maintained to be an inert gas atmosphere under normal pressure or pressure lower than the normal pressure, thereby preventing an unintended oxidation phenomenon of the polymer thin film or the porous dielectric material during removal of the trapped compounds. However, the heat treatment in the present invention does not exclude performing the heat treatment process in the air under normal pressure having an excellent effect as compared to a case where the heat treatment process is not performed.

In the present invention, sealing of the pores near the surface by the polymer thin film preferably means that it is completely sealed. However, the scope of the sealing of the present invention also includes that the sealing is partially performed or the size of the open pores of the surface is reduced by the polymer thin film. It is most preferred to perform the sealing to avoid external factors that are able to affect the porous dielectric material during actual post-processing by repeating the possible step of forming the thin film as needed to appropriately reduce open porosity of the porous dielectric material.

Hereinafter, an exemplary embodiment of the present invention is described in more detail. According to an exemplary embodiment of the present invention, there is provided a porous composite dielectric material including a porous dielectric material, and a polymer thin film formed on one surface or both surfaces of the porous dielectric material, wherein pores of a surface part of the porous dielectric material are sealed by the polymer thin film, and a change rate of a dielectric constant k satisfies Equation 1 below:

0≤[(k₂−k₁)/k₁]×100≤15 [Equation 1]

In Equation 1 above, k₁ is a dielectric constant of the porous dielectric material and k₂ is a dielectric constant of the porous composite dielectric material.

When the porous composite dielectric material satisfies the change rate of the dielectric constant k of 15% or less, more specifically, 0 to 10%, and is applied to the semiconductor device, process-related damage may be minimized during processing, and the original low dielectric constant may be maintained.

In an exemplary embodiment of the present invention, the polymer thin film may be formed by the iCVD process. More specifically, the polymer thin film may be formed on one surface or both surfaces of the porous dielectric material by the iCVD process. More preferably, a step of forming a polymer thin film on one surface or on both surfaces of the porous dielectric material by the iCVD process, and a step of performing heat treatment at a temperature higher than the substrate temperature of the chamber of the step of forming the polymer thin film to 400° C. or less may be repeated so that the change rate of the dielectric constant satisfies Equation 1.

In an exemplary embodiment of the present invention, the polymer thin film may have a thickness of 0 to 10 nm, and more specifically 0 to 3 nm, but the thickness is not limited thereto. The thickness of the polymer thin film is not limited. However, in an attempt to achieve the desired physical property such that the change rate of the dielectric constant k is 15% or less, and within the above range, when the thickness of the polymer thin film is excessively thick, the dielectric constant may be rather increased. Here, 0 nm means that the polymer thin film is not formed on the surface of the porous dielectric material but is filled only in the inside of the open pores near the surface.

In an exemplary embodiment of the present invention, the polymer thin film is not limited as long as it is a radically polymerizable monomer including at least one vinyl group. This monomer may be any one or two or more monomers selected from the group consisting of a fluorine-based monomer, an acrylic monomer, a silane-based monomer, a siloxane-based monomer, a silazane-based monomer, and a vinyl-based monomer, etc., and thus, no further description thereof is provided. Examples of the monomer of the present invention may include any one or a mixture of two or more selected from 1,3,5-trimethyl-2,4,6-trivinyl cyclotrisiloxane, 2,4,6-trimethyl-2,4,6-trivinylcyclotetrasilazane, 2,4,6,8-tetramethyl-2,4,6,8-tetravinylcyclotetrasiloxane, perfluorodecyl acrylate, cyclohexyl methacrylate, isobornyl acrylate, etc., and these examples are preferred to form a polymer thin film in which a change rate of a dielectric constant is low, but the monomer is not limited thereto.

In an exemplary embodiment of the present invention, the porous dielectric material before forming the thin film constituting the porous composite dielectric material may be a low-k porous dielectric material having k defined as 2.4 to 3.6 or a ultra low-k porous dielectric material having k defined as less than 2.4, and more specifically, 1.8 or more to less than 2.4. In an exemplary embodiment of the present invention, the porous dielectric material may have a refractive index of 1.20 to 1.24, but is not limited thereto.

In an exemplary embodiment of the present invention, a matrix, which is a porous dielectric material before forming the thin film constituting the porous composite dielectric material, is not particularly limited, but may have a pore size of 2 nm or more, and preferably 2 to 50 nm. A width of a trench or a via of the porous dielectric material on which the polymer thin film is to be formed is not limited as long as it is a width generally applied to a semiconductor device. Specifically, for example, the width thereof may be 5 to 200 nm, and more specifically 10 to 100 nm.

In an exemplary embodiment of the present invention, the porous dielectric material may be prepared using known methods such as chemical vapor deposition, spin-on glass, etc., but is not particularly limited as long as it is a dielectric material known in the art. Specifically, for example, the porous dielectric material may be selected from a porous SiCOH thin film, a porous polyarylene ether thin film, a porous silicon dioxide thin film, etc., but is not limited thereto.

According to another exemplary embodiment of the present invention, there is provided a semiconductor device including the porous composite dielectric material. More specifically, the semiconductor device may be a semiconductor device including the porous composite dielectric material as a dielectric film.

As a non-limiting specific example, a method of preparing a porous composite dielectric material of the present invention may include: a) placing a porous dielectric material on a substrate of an initiated chemical vapor deposition (iCVD) chamber; b) injecting a vaporized monomer or a vaporized monomer and a vaporized initiator into the chamber, and maintaining the chamber for a predetermined period of time, thereby adsorbing the monomer to a surface and internal pores of the porous dielectric material; c) forming a polymer thin film by applying heat while injecting the vaporized monomer and the vaporized initiator into the chamber, to thereby induce a chain polymerization reaction so that the monomers in a surface part of the porous dielectric material are polymerized; d) performing a heat treatment on the porous composite dielectric material having the polymer thin film formed thereon at a temperature of the substrate when the polymer thin film is formed or higher to 400° C. or lower; and e) repeating at least two cycles, wherein one cycle includes steps b), c), and d) that are sequentially performed.

More specifically, the method of preparing a porous composite dielectric material of the present invention may include: a) placing a porous dielectric material in an initiated chemical vapor deposition (iCVD) chamber; b) injecting a monomer or a monomer and an initiator that are vaporized at a substrate temperature of 10 to 100° C. and under a pressure of 10 to 1000 mTorr, thereby adsorbing the monomer to a surface and internal pores of the porous dielectric material; c) forming a polymer thin film by heating a filament in the chamber to a temperature at which the initiator is able to be pyrolyzed but the monomer is not affected while injecting the monomer and the initiator that are vaporized at the substrate temperature of 10 to 100° C. and under the pressure of 10 to 1000 mTorr, to thereby form free radicals so that the free radicals activate the monomer in a surface part of the porous dielectric material to induce a chain polymerization reaction, thereby polymerizing the monomer in the surface part of the porous dielectric material; d) performing a heat treatment on the porous composite dielectric material having the polymer thin film formed thereon at a temperature of a substrate when the polymer thin film is formed or higher to 400° C. or lower; and e) repeating at least two cycles, wherein one cycle includes steps b), c), and d) that are sequentially performed.

Hereinafter, each process in the method will be described in detail.

In an exemplary embodiment of the present invention, steps a), b), c) and d) may be performed in the same chamber or different chambers. More specifically, the heat treatment step in step d) may be performed in the same chamber as or different chamber from steps a), b), and c) of forming the polymer thin film.

In an exemplary embodiment of the present invention, the inside of the iCVD chamber may be provided with a substrate for placing the porous dielectric material and fixing a temperature of the porous dielectric material, and a filament for supplying heat.

In an exemplary embodiment of the present invention, an optional layer including any semiconductor device may be included between the porous dielectric material and the substrate of the chamber. That is, the optional layer including any semiconductor device may be formed on one surface of the porous dielectric material. This optional layer may include a silicon substrate, a copper film, etc., but is not limited thereto.

In the present invention, the porous dielectric material may be a low-k porous dielectric material having k defined as 2.4 to 3.6 or an ultra low-k porous dielectric material having k defined as less than 2.4, and more specifically, 1.8 or more to less than 2.4, but is not limited thereto.

In an exemplary embodiment of the present invention, the porous dielectric material may have a refractive index of 1.20 to 1.24, but is not limited thereto.

In an exemplary embodiment of the present invention, the porous dielectric material may be prepared using known methods such as chemical vapor deposition, spin-on glass, etc., but is not particularly limited as long as it is a dielectric material known in the art. Specifically, the porous dielectric material may be selected from a porous SiCOH thin film, a porous polyarylene ether thin film, a porous silicon dioxide thin film, etc., but is not limited thereto.

In an exemplary embodiment of the present invention, the porous dielectric material may have a pore size of 2 nm or more, and specifically 2 to 50 nm, but the pore size thereof is not limited thereto.

In an exemplary embodiment of the present invention, a width of a trench or a via of the porous dielectric material on which the polymer thin film is to be formed is not limited as long as it is a width generally applied to a semiconductor device. Specifically, for example, the width thereof may be 5 to 200 nm, and more specifically 10 to 100 nm, but is not limited thereto.

In an exemplary embodiment of the present invention, steps b) and c) are to form the polymer thin film, wherein the vaporized monomer or the vaporized monomer and initiator may be injected into the chamber and the monomer may be adsorbed to the surface and the internal open pores of the porous dielectric material, and then, heat may be applied while continuously injecting the vaporized monomer or the vaporized monomer and initiator into the chamber, thereby pyrolyzing the initiator to induce the chain polymerization reaction. Here, when the monomer or the monomer and the initiator are injected, an inert gas may be used and injected as needed. Specifically, for example, one or two or more carrier gases selected from Ar, N₂ and He, etc., may be used and injected, but the gas is not limited thereto. In addition, the carrier gas may be selectively used, and is not necessarily used.

In an exemplary embodiment of the present invention, the monomer means a unit that is usable to form a polymer thin film near the surface of the porous dielectric material. The monomer is a volatile material capable of being activated by the initiator, and may be vaporized under reduced pressure and in an increased temperature state, and is not limited as long as it has at least one vinyl group. In addition, it is more preferred to use a material having a low dielectric constant.

In an exemplary embodiment of the present invention, the monomer may be any one or two or more selected from the group consisting of a fluorine-based monomer, an acrylic monomer, a silane-based monomer, a siloxane-based monomer, a silazane-based monomer, and a vinyl-based monomer, etc., each including at least one vinyl group. More preferably, the monomer may be the siloxane-based monomer including at least one vinyl group, the silazane-based monomer including at least one vinyl group or the acrylic monomer including at least one vinyl group. More specifically, for example, the monomer may be any one selected from 1,3,5-trimethyl-2,4,6-trivinyl cyclotrisiloxane, 2,4,6-trimethyl-2,4,6-trivinylcyclotetrasilazane, 2,4,6,8-tetramethyl-2,4,6,8-tetravinylcyclotetrasiloxane, perfluorodecyl acrylate, cyclohexyl methacrylate, isobornyl acrylate, etc., or a mixture thereof, as an example of the monomer having a low dielectric constant, but is not limited thereto.

In an exemplary embodiment of the present invention, it is preferred that the pressure of the chamber in step b) is controlled so that the monomer is easily adsorbed, and more preferably, as a fractional saturation ratio (Pm/Psat) of a monomer vapor is higher, the monomer may be more favorably adsorbed to the open pores of the porous dielectric material. However, when the Pm/Psat is excessively high, the monomer may be adsorbed not only to the open pores of the porous dielectric material but also to the surface of the dielectric material. Although the present invention does not exclude this situation, when the monomer is excessively adsorbed to the surface of the dielectric material, the thickness of the finally formed porous composite dielectric material may be excessively increased. Although the pressure of the chamber is not limited as a condition for satisfying the above pressure, specifically, for example, it is more preferred to control the pressure to 10 to 1000 mTorr so that the monomers are sufficiently filled in the open pores in the porous dielectric material, and the monomers having a thickness of several atomic layers are adsorbed to the surface of the dielectric material, thereby minimizing an increase in thickness of the final porous composite dielectric material. More preferably, the pressure is preferably controlled to 10 to 100 mTorr since the monomers are adsorbed only to the open pores of the porous dielectric material, and the adsorption of the monomer having a thickness of a single atom layer or less to the surface of the dielectric material is induced so as not to increase the thickness of the final porous composite dielectric material, but is not limited thereto.

In order to ensure adsorption to only the surface part of the porous dielectric material, a flow rate and time at which the monomer or the monomer and the initiator is injected may be controlled, for example, the flow rate may be 0.1 to 1000 sccm, and more specifically 1 to 50 sccm, and the time may be 0.1 to 100 seconds, and more specifically 0.1 to 10 seconds, but the present invention is not limited thereto.

In an exemplary embodiment of the present invention, the initiator is a material that induces activation of a first reaction so that the monomer is able to form the polymer in the process of the present invention. The initiator may be used without limitation as long as it is a material capable of being pyrolyzed at a temperature lower than a temperature at which the monomer is pyrolyzed to form free radicals. More specifically, the initiator may be used without limitation; as long as it is pyrolyzed at 50 to 300° C. to generate the free radicals.

The free radicals formed through the pyrolysis of the initiator transfer radicals to the vinyl groups in the monomer to induce the chain reaction, thereby forming the polymer, and the thus-formed polymer material is deposited near the surface of the porous dielectric material. A driving force used in the polymer polymerization reaction is a heat source used to activate the initiator. Since various types of monomer materials are not chemically damaged at a temperature at which the initiator is activated, the monomer materials may be converted to the polymer thin film while maintaining various functional groups possessed by the monomer as they are.

In an exemplary embodiment of the present invention, the initiator is not limited as long as it is a conventional radical initiator, and for example, may include a redox-based initiator, an azo-based initiator, a peroxide-based initiator, etc. The initiator is not specifically limited as long as it is generally usable in this field.

In an exemplary embodiment of the present invention, the initiator may be a peroxide-based initiator, and for example, may be any one or a mixture of two or more selected from dialkyl peroxyketal, dialkyl peroxide, di(alkylperoxy)alkylene, di(alkylperoxy)aralkylene, etc. More specifically, for example, the initiator may be di-tert-butyl peroxide, 1,1-(t-butylperoxy)cyclohexane, and 1,1-(t-butylperoxy)-3,3,5-trimethylcyclohexane, etc., but is not limited thereto.

In an exemplary embodiment of the present invention, it is preferred that the pressure of the chamber in step c) is maintained as the pressure formed in step b) in order to minimize process variables, but is not limited thereto. Specifically, the pressure may be controlled to 10 to 1000 mTorr, preferably 10 to 250 mTorr, and more preferably 10 to 100 mTorr, but is not limited thereto.

In addition, the process of inducing the chain polymerization reaction in step c) may provide heat by a conventional method in which heat is able to be provided in a gas phase, thereby pyrolyzing the initiator. Specifically, the heat may be provided by using a filament, and a temperature of the provided heat may be 50 to 300° C., and more preferably 100 to 250° C. Within this range, it is preferred since the radicals may be generated by breaking bonds of the initiator without damaging the monomer, but the present invention is not limited thereto. In addition, temperatures of the substrate, and a sample placed on the substrate, i.e., the porous dielectric material and all devices below it in the step of applying heat may be maintained at a temperature intended by the user. More specifically, the temperature may be maintained at 10 to 100° C., and more preferably 30 to 60° C. so that the polymer thin film is more easily formed.

In an exemplary embodiment of the present invention, heat is provided by a tungsten filament heated to a set temperature in a vacuum chamber environment in which the vaporized or sublimed monomers and initiator are present, and thus, the initiator is pyrolyzed to generate the free radicals, and the monomers in the surface part of the porous dielectric material which is accessible by the radicals, are polymerized to achieve polymerization near the surface, and thus, the polymer thin film is formed.

In an exemplary embodiment of the present invention, the step of forming free radicals means pyrolyzing the initiator through the step of injecting heat to form the free radicals.

In an exemplary embodiment of the present invention, the step of forming the polymer thin film may activate the monomers by using free radicals formed by pyrolysis, thereby forming the polymer through the chain polymerization reaction from the monomers, and forming the polymer thin film inside the open pores of the surface of the porous dielectric material and the surface including the open pores. That is, in the step of forming the polymer thin film, when the free radicals are formed by the pyrolysis of the initiator, the free radicals activate the monomers to induce polymerization, and the reaction continues to form the polymer thin film.

In an exemplary embodiment of the present invention, the heat treatment in step d) is performed to remove the monomer, the initiator or the oligomer that is not sufficiently polymerized which are trapped in the porous composite dielectric material in the process of forming the polymer thin film near the surface of the porous dielectric material. The heat treatment may minimize reduction in the dielectric constant and reduction in internal porosity of the dielectric material according to conversion from the open pores to the closed pores after the surface of the porous composite dielectric material is sealed.

In an exemplary embodiment of the present invention, the heat treatment may be performed in a vacuum or in an inert gas atmosphere under normal pressure or a pressure lower than the normal pressure. More specifically, the heat treatment may be performed at any one or two or more gas atmosphere selected from Ar, N₂, He, etc.

In an exemplary embodiment of the present invention, it is preferred that the temperature during the heat treatment in step d) is higher than a temperature of the substrate when the polymer thin film is formed to 400° C. or less since it is possible to satisfy heat tolerance degree of a semiconductor post-process while discharging the trapped material inside, but the temperature is not limited thereto. More specifically, the heat treatment may be performed at a temperature higher by 5° C. or more, and more specifically 5 to 200° C. than the temperature of the substrate in the step of forming the polymer thin film. Specifically, the heat treatment may be performed at 40 to 400° C., and more preferably 80 to 300° C. for 1 to 30 minutes, and more preferably for 1 to 10 minutes, thereby easily removing unreacted materials that are trapped inside, and minimizing damage of the polymer thin film, but the present invention is not limited thereto.

Here, step d) may be performed in the same chamber as steps b) and c) or may be performed in a separate heat treatment chamber. When the heat treatment is performed in the same chamber, supply of the vaporized initiator and monomer may be stopped, followed by vacuum exhaust or purging with an inert gas, and then the heat treatment may be performed at a temperature higher than that of the step of forming the thin film. In addition, when the heat treatment is performed in the same chamber, a cooling step may be further included before repeating steps b) and c).

Further, at the time of the heat treatment of step d), the atmosphere in the iCVD chamber is controlled to be a vacuum state or an inert gas atmosphere, and then, the temperature of the substrate on which the sample in the chamber is placed may be controlled to a temperature of the substrate on which the porous dielectric material of step c) is placed or higher to 400° C. or less.

In an exemplary embodiment of the present invention, step e) is performed by repeating at least two cycles, wherein one cycle includes step b) of adsorbing the monomer, step c) of depositing the polymer thin film, and step d) of performing the heat treatment that are sequentially performed. That is, after steps b) and c) are performed, step d) of the heat treatment may be performed, and then, after steps b) and c), step d) may be repeated. When at least two cycles are performed in step e), respective monomers and initiators used in the step of adsorbing the monomer and the step of depositing the polymer thin film in each cycle may be the same, or may be partially the same, or may be all different. Further, process conditions applied in each adsorption and deposition process may be the same, or may be partially the same, or may be all different.

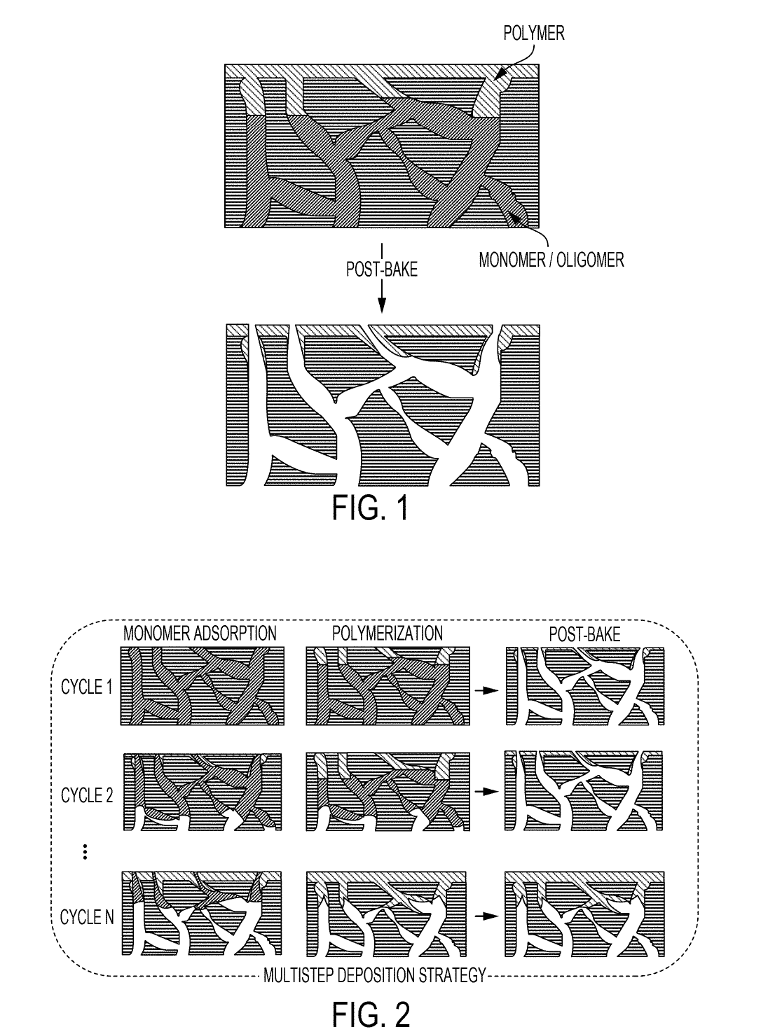

When the refractive index and the dielectric constant of the porous composite dielectric material are measured after step b) of adsorbing the monomer and step c) of depositing the polymer thin film are performed, the refractive index and the dielectric constant are increased as compared to those of an initial porous dielectric material. Accordingly, only the monomers adsorbed on the open pores near the surface which is accessible by the radicals are polymerized, and only the unreacted monomer or the oligomer having a small molecular weight by partial reaction remains inside of the porous composite dielectric material. The presence of these trapped materials causes a great increase in an effective dielectric constant of the porous composite dielectric material, and thus, these trapped materials may be effectively removed through the heat treatment in step d). One cycle is defined as a case where step b), step c) and step d) are performed once, and this reaction mechanism is shown in FIGS. 1 and 2. In FIGS. 1 and 2, post-bake means the heat treatment process, and a polymer means the polymer thin film.

In an exemplary embodiment of the present invention, the repeating in step (e) may be terminated at a time when a variation width n_{rof} of a refractive index satisfies Equation 3 below:

0≤n_{rof}≤0.1 [Equation 3]

In Equation 3, n_{rof}=|n_{f}−n_{f-1}|, n_{f-1} is a refractive index of the porous dielectric material measured after step c), and n_{f} is a refractive index of the porous dielectric material measured after step d).

However, the above described range means, in view of a practical aspect, a state in which the surface of the porous dielectric material is sealed sufficiently in a post-process even if the surface of the porous dielectric material is not completely sealed. More preferably, 0≤n_{rof}≤0.02 may be satisfied. Here, 0.02 or less includes an error range, which means that there is substantially no change in the refractive index.

When the polymer thin film is formed according to the preparation method of the present invention, it is possible to provide the porous composite dielectric material in which the change rate of the dielectric constant k according to Equation 1 is 15% or less, and more preferably 10% or less:

0≤[(k₂−k₁)/k₁]×100≤15 [Equation 1]

In Equation 1 above, k₁ is a dielectric constant of the porous dielectric material and k₂ is a dielectric constant of the porous composite dielectric material.

In an exemplary embodiment of the present invention, as conditions for satisfying Equation 1, in steps b) and c), the temperature of the substrate may be 10 to 100° C., the chamber pressure may be 10 to 1000 mTorr, and more preferably, 10 to 100 mTorr, the deposition time may be 1 to 500 seconds, and the temperature at which the initiator is pyrolyzed may be 50 to 300° C., but these are not limited thereto. Within the above range, the monomer vaporized and injected in step b) may be sufficiently filled in the open pores of the porous dielectric material, while simultaneously minimizing the adsorption on the surface of the dielectric material.

Hereinafter, the present invention is described in detail on the basis of Example Meanwhile, the following Examples are provided by way of example for explaining the present invention in more detail, and therefore, the present invention is not limited thereto.

Hereinafter, physical properties were measured by the following methods.

1) Thickness and Refractive Index

A total thickness and a refractive index of a porous dielectric material before treatment and a porous composite dielectric material on which a polymer thin film which is a pore sealing layer was formed, were measured using spectroscopic ellipsometry (M-2000D manufactured by J. A. Woollam Co.).

2) Porosity

Porosity was measured using Ellipsometric porosimetry (SOPRA EP5 manufactured by SemiLab Co., Ltd.).

The porosity is measured in a manner in which the spectroscopic ellipsometry is combined with a system capable of adsorbing an evaporated solvent on the sample, and specifically, optical characteristics that are changed as solvent vapor is adsorbed/desorbed on/from the sample are measured, and then, an open porosity of the sample is calculated from the measured optical characteristics. The solvent used is toluene.

3) Effective Dielectric Constant (k_{eff})

A platinum dot was formed on an initial ultra low-k porous dielectric material and a porous composite dielectric material on which the polymer thin film is formed, and capacitance was measured using a precision LCR meter (E4980A Precision LCR Meter manufactured by Agilent Technologies), and k_{eff} was calculated using the previously measured thickness and dot area.

### Example 1

A porous SiCOH thin film having ultra low-k (ULK) characteristics was used as a porous dielectric material. The used ultra-low-k porous SiCOH thin film was deposited on a Si substrate at a thickness of 90 nm, wherein the k value was 2.0 and the porosity was 45%. Further, the refractive index was 1.21.

1) Process of Forming a Polymer Thin Film

The porous dielectric material was placed on a substrate in an iCVD chamber, wherein a substrate temperature was maintained at 40° C. A chamber pressure was increased to 100 mTorr while injecting the vaporized monomer and initiator into the chamber. After the chamber pressure was immobilized at 100 mTorr, the reaction materials were subjected to stabilization for about 5 seconds so that the monomers could be sufficiently adsorbed in the open pores of the porous dielectric material. Subsequently, a filament temperature was heated to 200° C. while continuously injecting the vaporized monomer and initiator, and maintained for 60 seconds to induce polymerization of the monomer near the surface of the porous dielectric material. The monomer was 1,3,5-trimethyl-2,4,6-trivinylcyclotrisiloxane (V3D3), and the initiator was di-tert-butyl peroxide (d-TBPO). A flow ratio of the monomer to the initiator was fixed to a ratio of 170:80.

2) Heat Treatment Process

Then, the supply of the initiator and the monomer was stopped, the inside of the chamber was sufficiently depressurized, and then the chamber was vented to remove the porous dielectric material in which the polymer is deposited from the chamber. Next, a heat treatment process was performed on a separate hot plate. Here, the hot plate was present in a glove box maintained in an argon gas atmosphere under normal pressure. The heat treatment was performed on a hot plate in the glove box at 200° C. for 5 minutes.

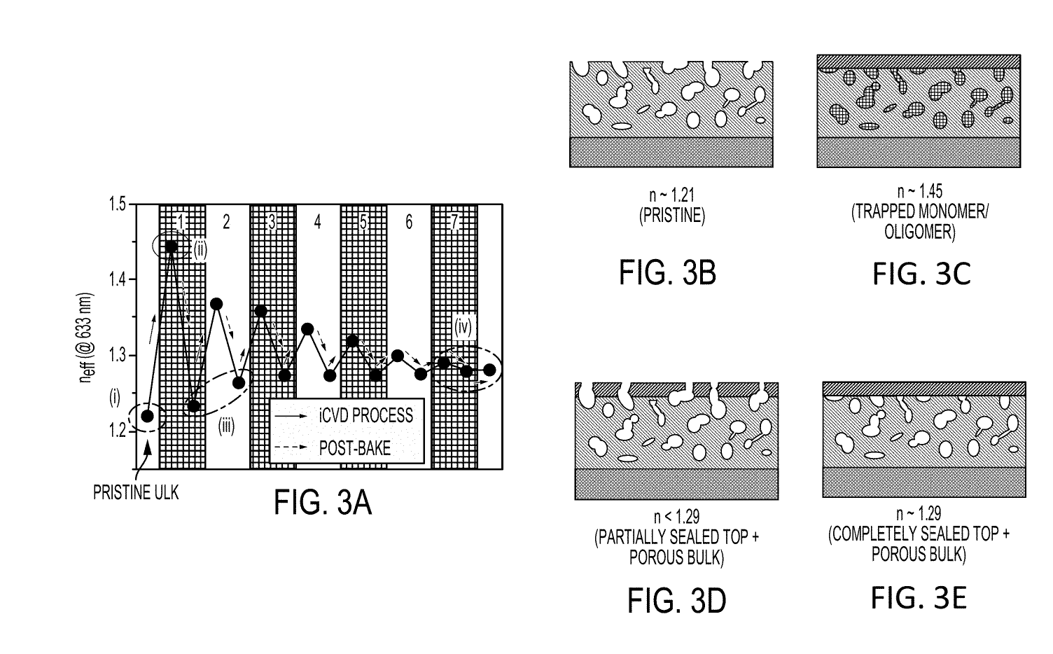

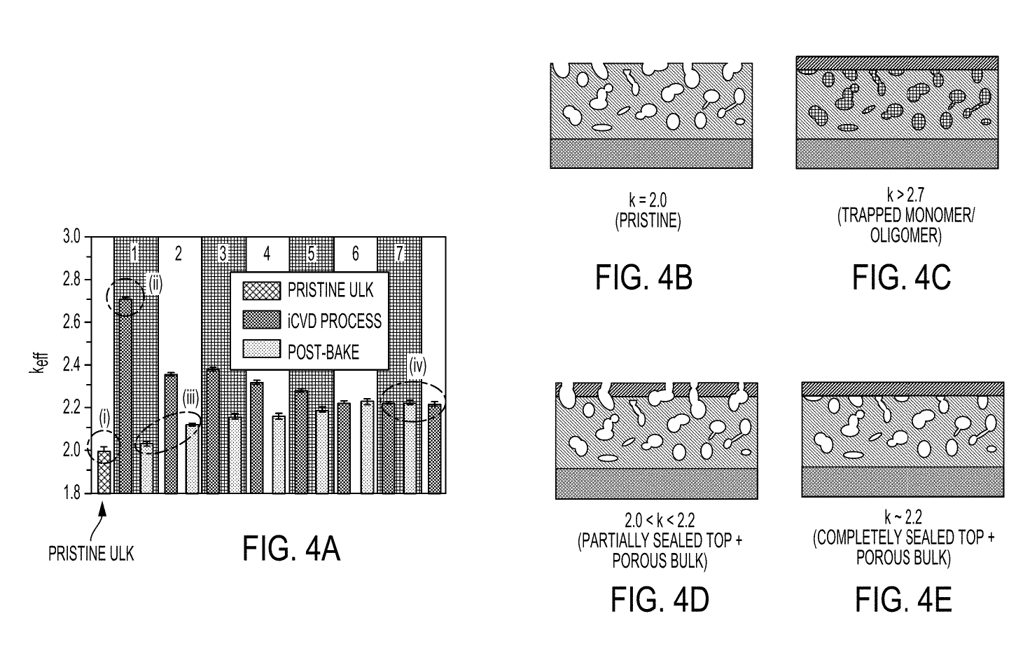

The process of adsorbing the monomer to form the polymer thin film and the heat treatment process were repeated seven times in sequence under the same conditions, and as a result, as shown in FIGS. 3A-3E and FIGS. 4A-4E, it was confirmed that the dielectric constant of the prepared dielectric material was 2.2, the change rate of the dielectric constant thereof was 10%, and the refractive index was 1.29, and thus, the original low dielectric constant was well maintained even though the polymer thin film was formed on the surface of the dielectric material.

In particular, as shown in FIGS. 4A-4E, it was confirmed that as the process of depositing the polymer thin film on the porous dielectric material having an initial refractive index of 1.21 and the heat treatment process were repeated, a change amount of the effective reflective index (n_{eff}) was decreased and immobilized after the seventh cycle. That is, the porous dielectric material initially had a very low refractive index due to the porosity, but when the polymer thin film was formed by applying the iCVD process to the porous dielectric material, the refractive index was greatly increased to 1.45 due to the polymer thin film formed near the surface of the dielectric material and the monomer and oligomer trapped inside the dielectric material. In addition, when a primary heat treatment was performed, it was confirmed that the materials trapped in the inner part penetrated through the polymer thin film at the upper part and were discharged to the outside, thereby restoring the inner porosity, and thus, the refractive index was reduced to 1.24 again. Here, the reduced refractive index was somewhat higher than the initial refractive index, which indicated that some of the polymer thin film remained even though the trapped materials were discharged to the outside and destroyed the upper polymer thin film. As the cycles were repeated, the variation width of n_{eff} was decreased, which indicated that the materials trapped inside the porous composite dielectric material were gradually decreased, and as a result, as the cycle was repeated, an effect of partial sealing the surface of the porous composite dielectric material was gradually strengthened. It was shown that the variation width of the refractive index completely disappeared after the seventh cycle, which indicated that the surface of the porous dielectric material was completely sealed.

In addition, as shown in FIGS. 3A-3E, it is confirmed that the effective dielectric constant (k_{eff}) was also changed as the cycles were repeated. Similar to the refractive index, when the polymer thin film was formed by applying the iCVD process to the porous dielectric material initially having a very low dielectric constant of 2.0, a high k_{eff} was shown, and was reduced again after the heat treatment process. Here, the reduced k_{eff} value was somewhat higher than the initial k_{eff}, which also proved that some polymers remained on the surface of the porous dielectric material. It was confirmed that as the iCVD process and the heat treatment process were repeated, the variation width of k_{eff} was reduced, and the variation width completely disappeared from the sixth cycle.

The change rate of the dielectric constant was calculated according to Equation 1 and was confirmed as 10%.

<Evaluation of Sealing Property of Polymer Thin Film>

When a copper (Cu) barrier was formed using a metal precursor on the polymer thin film formed on the surface of the dielectric material formed through the seventh cycle of Example 1, a property experiment was conducted to determine whether the surface sealing by the polymer thin film effectively prevents penetration of the metal precursor into the porous composite dielectric material.

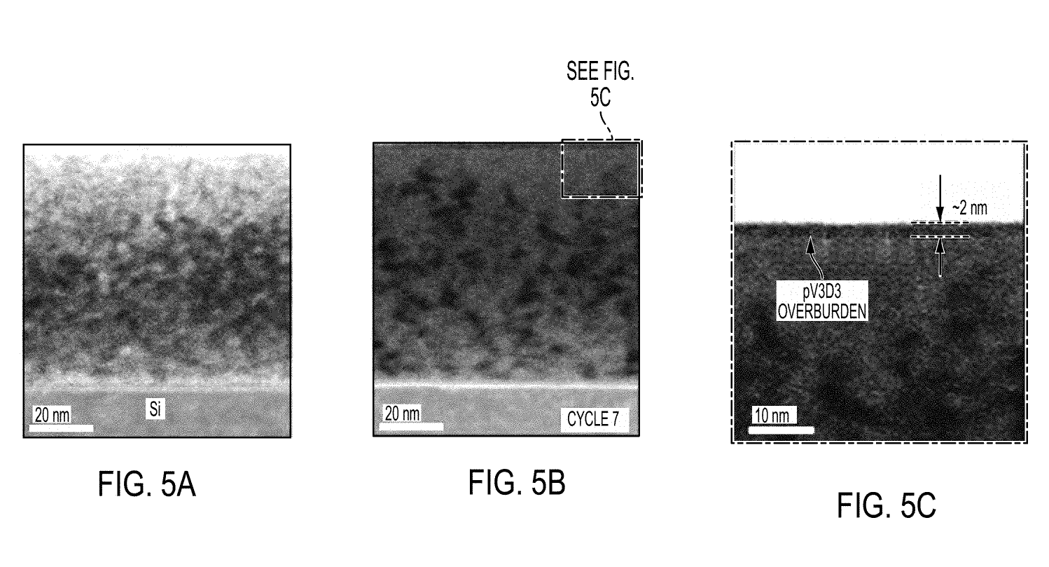

For the test, tetrakis (dimethylamido) titanium (TDMAT) and ammonia were reacted in an atomic layer deposition (ALD) chamber at 200° C. to form a titanium nitride (TiN) thin film using a direct capacitive coupled plasma (CCP, 13.56 MHz) in an argon atmosphere. As a result, when the ALD TiN layer was deposited on the initial porous dielectric material as shown in FIG. 5A, the TDMAT precursor penetrated into the entire of the porous dielectric material. On the other hand, as shown in FIG. 5B, in the surface-sealed porous composite dielectric material, the ALD TiN layer was deposited on only an upper part of the surface of the porous composite dielectric material, and the penetration of the TDMAT precursor into the dielectric material was completely prevented. Further, it could be appreciated from FIG. 5C that the polymer thin film formed by repeating the cycles seven times still had a very thin thickness of 2 nm, and the porosity of the inside of the dielectric material under the polymer thin film still remained.

### Example 2

In Example 2, the deposition and the heat treatment were performed in the same manner as in Example 1 except that the process pressure in the iCVD chamber was changed to 300 mTorr, and it was confirmed that when the deposition was repeated six times in total, the change in the refractive index was reduced to 0.01 or less. It was confirmed that the k_{eff} was 2.2, and the penetration of the TDMAT precursor was completely prevented.

### Example 3

In Example 3, the deposition and the heat treatment were performed in the same manner as in Example 1 except that the process pressure in the iCVD chamber was changed to 500 mTorr, and it was confirmed that when the deposition was repeated five times in total, the change in the refractive index was included within the error range.

### Example 4

In Example 4, the deposition and the heat treatment were performed in the same manner as in Example 1 except that the monomer was changed to 2,4,6,8-tetramethyl-2,4,6,8-tetravinylcyclotetrasiloxane, it was confirmed that when the deposition was repeated seven times in total, the change in the refractive index was included within the error range.

The porous composite dielectric material according to the present invention is characterized in that the open pores of the surface of the porous dielectric material are sealed by the polymer thin film, and the compounds, etc., that are trapped during the sealing are removed or partially immobilized by a specific heat treatment means of the present invention, and thus, when the porous composite dielectric material is applied to a semiconductor device, it is possible to minimize the change of physical properties due to the post-process, and even if the surface is sealed by the polymer thin film, the change rate of the dielectric constant is low, and thus, an original low dielectric constant of the porous dielectric material is capable of being maintained. Therefore, a more favorable dielectric effect is able to be achieved when the porous composite dielectric material is applied to the semiconductor device.

In addition, the method of sealing the open pores of the surface of the porous dielectric material of the present invention uses the initiated chemical vapor deposition (iCVD) method, and thus, only the monomers for forming a polymer layer, the initiator for initiating a polymerization reaction, and radicals formed by pyrolysis of the initiator are present, which reduces damage to the porous dielectric material.

Further, a very thin polymer thin film may be formed by controlling the deposition conditions as shown in Equation 2, thereby maintaining an original low dielectric constant property of the porous dielectric material. In addition, when the monomers in which a polymer thin film having a low k value is formed are selected and used at the time of forming a polymer, deterioration of the low dielectric constant property may be minimized.

In addition, the polymer thin film of the present invention has a good step coverage due to a surface-growing mechanism of iCVD, which may provide a very suitable method for a semiconductor post-process interconnect structure having a large aspect ratio.

What is claimed is:

1. A porous composite dielectric material comprising:
a porous dielectric material, and
a polymer thin film formed on one surface or both surfaces of the porous dielectric material,
wherein pores of a surface part of the porous dielectric material are sealed by the polymer thin film, and
a change rate of a dielectric constant k satisfies Equation 1 below:
0≤[(k₂−k₁)/k₁]×100≤15
wherein in Equation 1 above, k₁ is a dielectric constant of the porous dielectric material and k₂ is a dielectric constant of the porous composite dielectric material.

2. The porous composite dielectric material of claim 1, wherein the polymer thin film is formed by an initiated chemical vapor deposition (iCVD) process.

3. The porous composite dielectric material of claim 1, wherein the polymer thin film has a thickness of 0 to 10 nm.

4. The porous composite dielectric material of claim 1, wherein the polymer thin film includes a polymer derived from any one or two or more monomers selected from the group consisting of a fluorine-based monomer, an acrylic monomer, a silane-based monomer, a siloxane-based monomer, a silazane-based monomer, and a vinyl-based monomer, each including at least one vinyl group.

5. The porous composite dielectric material of claim 1, wherein the porous dielectric material has a pore size of 2 nm to 50 nm.

6. A semiconductor device comprising the porous composite dielectric material of claim 1.

7. A method of preparing a porous composite dielectric material comprising:
a) placing a porous dielectric material on a substrate of an initiated chemical vapor deposition (iCVD) chamber;
b) injecting a vaporized monomer or a vaporized monomer and a vaporized initiator into the chamber, and maintaining the chamber for a predetermined period of time, thereby adsorbing the monomer to a surface and internal pores of the porous dielectric material;
c) forming a polymer thin film by applying heat while injecting the vaporized monomer and the vaporized initiator into the chamber, to thereby induce a chain polymerization reaction so that the monomers in a surface part of the porous dielectric material are polymerized;
d) performing a heat treatment on the porous composite dielectric material having the polymer thin film formed thereon at a temperature of the substrate when the polymer thin film is formed or higher to 400° C. or lower; and
e) repeating at least two cycles, wherein one cycle includes steps b), c), and d) that are sequentially performed.

8. The method of claim 7, wherein in steps b) and c), the temperature of the substrate on which the porous dielectric material is placed is 10 to 100° C., and a pressure in the chamber is 10 to 1000 mTorr.

9. The method of claim 7, wherein when the monomer or the monomer and the initiator is injected in steps b) and c), an inert gas is used.

10. The method of claim 7, wherein the repeating in step (e) is terminated when a variation width n_{rof} of a refractive index satisfies Equation 3 below:
0≤n_{rof}≤0.1
wherein in Equation 3, n_{rof}=|n_{f}−n_{f-1}|, n_{f-1} is a refractive index of the porous dielectric material measured after step c), and n_{f} is a refractive index of the porous dielectric material measured after step d).

11. The method of claim 7, wherein step d) is performed by maintaining the porous composite dielectric material in the chamber or by transferring the porous composite dielectric material to a separate heat treatment chamber.

12. The method of claim 7, wherein in step d), when the porous composite dielectric material is maintained in the chamber, the heat treatment is performed after supply of the initiator and the monomer is stopped, followed by vacuum exhaust or purging with inert gas.

13. The method of claim 7, wherein the heat treatment in step d) is performed in a vacuum, an inert gas atmosphere under normal pressure, and an inert gas atmosphere under reduced pressure.

14. The method of claim 9, wherein the inert gas is any one or two or more selected from Ar, N₂ and He.

15. The method of claim 13, wherein the inert gas is any one or two or more selected from Ar, N₂ and He.

16. The method of claim 7, wherein the heat treatment in step d) is performed at a temperature of 40 to 400° C.
